(19) United States
(12) Patent Application Publication
(10) Pub. No.: US 2007/0057277 A1
(43) Pub. Date: Mar. 15, 2007

(54) Tunneling gap diodes

(76) Inventors: Artemi Martsinovsky, St. Petersburg (RU); Isaiah Watas Cox, Baltimore, MD (US)

Correspondence Address: Borealis Techincal limited, 23545 NW Skyline BLVD, North Plains, OR, 97133-9205, US

(21) Appl. No.: 10/573,239

(22) PCT Filed: Sep. 22, 2004
(86) PCT No.: PCT/US04/31221

§ 371 Date: Mar. 22, 2006

(51) Int. Cl. H01L 29/00

(52) U.S. Cl. 257/104

(57) ABSTRACT

The present invention discloses a tunneling diode having a band gap material as the collector. This increases the tunneling of electrons having greater energy than the Fermi level from emitter to collector, leading to an increase in the efficiency of heat pumping or power generation by the diode. This approach also reduces back tunneling of electrons from collector to emitter.

### TECHNICAL FIELD

This invention relates to tunneling diodes and their application to heat pumping and power generation.

### BACKGROUND ART

Tunnel junctions of a new type that comprise Normal metal-Vacuum-Normal metal (NVN) have been disclosed [Avto Tavkhelidze, Larisa Koptonashvili, Zauri Berishvili, Givi Skhiladze, “Method for making diode device”, U.S. Pat. No. 6,417,060 B2]. A key advantage of these junctions is the use of a vacuum as the insulator. Consequently, there is formally zero heat conductivity between the electrodes, allowing the fabrication of tunnel junctions with extremely low thermal backflow.

Other groups have reported theoretical studies that seek to utilize the benefits of using a vacuum as an insulator. One group has considered utilizing tunnel emission through semiconductor resonant states [A. N. Korotkov and K. K. Likharev, “Possible cooling by resonant Fowler-Nordheim emission”, Appl. Phys. Lett. 75 (16):2491-2493 (1999)]. This approach leads to a selective emission of electrons from the cathode and improves the efficiency of the device. Another group proposes cooling via electron field emission from diamond or III-nitride thin films deposited on metal or silicon substrates [P. H. Cutler, N. M. Miskovsky, N. Kumar and M. S. Chung, “New Results on Microelectronic Cooling Using the Inverse Nottingham Effect. Low temperature Operation and Efficiency”, Electrochemical Soc. Proc. Volume 2000-28, pp 99-111 (1999)]. A yet further theoretical study has considered how the effective work function for emission may be lowered by reducing the gap between the electrodes to a nanometer, and it is predicted that a material having a work function of −1.0 eV would show an effective work function of ˜0.4-0.3 eV or less under these conditions [Y. Hishinuma, T. H. Geballe, B. Y. Moyzhes, T. W. Kenny, “Refrigeration by combined tunneling and thermionic emission in vacuum: Use of nanometer scale design”, Appl. Phys. Lett. 78(17):2752-2754, (2001)]. Experimental work using a small nm-sized gap showed the expected lowering of the vacuum barrier between the electrodes, enabling emission from surfaces with work functions of ˜1 eV at room temperature [Y. Hishinuma, T. H. Geballe, B. Y. Moyzhes, T. W. Kenny, “Measurements of cooling by room-temperature thermionic emission across a nanometer gap”, Appl. Phys. Lett. 94(7):4690-4696, (2003)]. Further theoretical work from this group has suggested that the need for materials with work functions near 1.0 eV (which is difficult to achieve in practice), may be circumvented by the use of a semiconductor layer on the emitter in combination with a strong electric field [Y. Hishinuma, T. H. Geballe, B. Y. Moyzhes, T. W. Kenny, “Vacuum thermionic refrigeration with a semiconductor heterojunction structure”, Appl. Phys. Lett. 81(22):4242-4244, (2002)].

It is well known that thermionic diodes offer the possibility of efficient cooling: every electron that leaves the emitter carries away energy WF+2 kT (where WF is the work function of the emitter electrode). However, for room temperature cooling effects, materials having work functions of the order of ˜0.3-0.35 eV are needed for the emitter, and such materials are not practically available.

For tunnel diodes having metal electrodes the situation is different. All the electrons can tunnel (though with different probability), whether they have an energy level above the Fermi level (E_{f}), or below. Those electrons which have energy E above the Fermi level, carry away energy E−Ef; those electrons which have E<Ef, return energy Ef−E to the emitter. As a result, the sum effect is significantly less than with thermionic diodes. Even if the work function is reduced to ˜0.3-0.35 eV by an applied bias voltage, common tunnel diodes with metal electrodes thus have two major drawbacks: (i) electrons below the Fermi level may tunnel; (ii) electrons may back tunnel from anode to cathode. As a result, high cooling power up to 10 W/cm² and more may be obtained, but at very low efficiency (˜1% or less). Thus approaches, such as those described by Korotkov and Likharev (1999) and by Hishinuma et al. (2002), which use selective emission from above Fermi level states, have relatively high efficiency. But even in these cases, the efficiency is far from Carnot one, and these methods, (especially the latter) impose additional technological difficulties for tunnel diode creation, which at the nm scale is extremely difficult.

### DISCLOSURE OF INVENTION

From the foregoing, it may be appreciated that a need has arisen for an improved tunneling gap diode in which only electrons above the Fermi level tunnel from emitter to collector, and in which back tunneling, from collector to emitter, is suppressed.

The present invention discloses a tunneling diode having a band gap material as the collector, or having a metal electrode coated by a film of band gap material with a thickness greater than the mean distance of relaxation of tunneled emitter electrons (˜10 nm or more). This increases the tunneling of electrons having greater energy than the Fermi level from emitter to collector, leading to an increase in the efficiency of heat pumping or power generation by the diode. In the context of this invention, the term “band gap material” is defined as a crystal material having a filled zero temperature valence band and an empty conductive band. The band gap material may be a material such as a dielectric or semiconductor.

In a further embodiment, the tunneling diode may have the same or different band gap material as emitter, or a metal emitter, coated by the same or different band gap material. This not only increases the tunneling of electrons having greater energy than Fermi level from emitter to collector but also suppresses partially the back emission from anode to cathode, leading to an increase in the efficiency of heat pumping or power generation by the diode.

For these embodiments, the band gap material may be present as a layer of band gap material, or may be a hetero-structured band gap layer.

The present invention also comprises a method for promoting the tunneling of electrons having an energy level higher than the Fermi level from an emitter surface, comprising the step of positioning a collector comprising a band gap material at a distance within the tunneling range of the electrons

The present invention also comprises a method for suppressing back tunneling of electrons from collector to emitter by using a collector comprised of a band gap material.

The present invention also comprises a vacuum diode heat pump for heat pumping applications comprising the tunneling diode of the present invention.

The present invention also comprises an electrical power generator comprising the tunneling diode of the present invention.

### BRIEF DESCRIPTION OF DRAWINGS

For a more complete explanation of the present invention and the technical advantages thereof, reference is now made to the following description and the accompanying drawing in which:

FIG. 1 shows two embodiments of a tunnel diode device of the present invention.

FIG. 2 shows in diagrammatic form various energy levels of a close-spaced tunnel diode of the present invention.

FIG. 3 shows two embodiments of a tunnel diode device of the present invention for pumping heat or power generation.

### BEST MODE FOR CARRYING OUT THE INVENTION

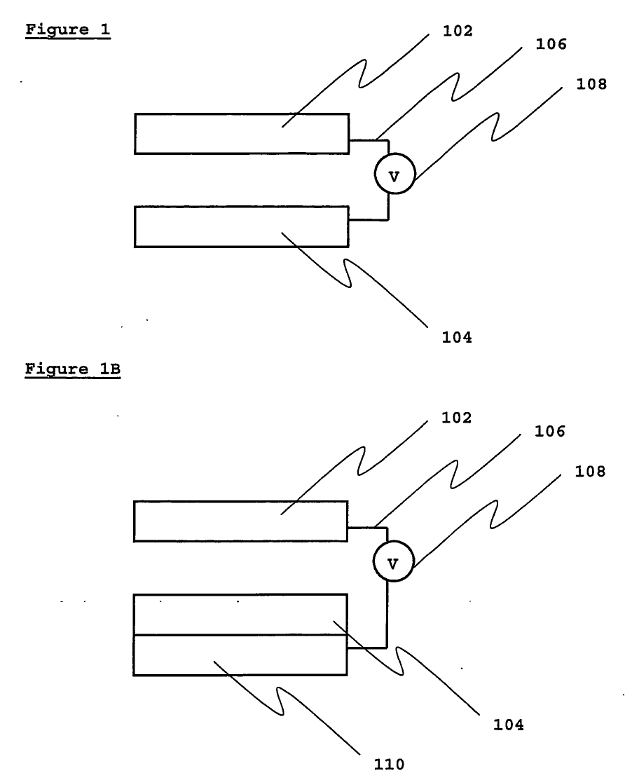

Embodiments of the present invention and their technical advantages may be better understood by referring to FIG. 1A, which shows in diagrammatic form a tunnel diode comprising a metal emitter 102, a collector 104, an external circuit 106 and a voltage source, 108. The collector comprises a band gap material, which is to be understood in this present disclosure to indicate a material in which there is a forbidden region between a lower valence band and an upper conduction band. The band gap material may be a semiconductor, such as Ge, Si, GaAs or SiC. The band gap material may be a hetero-structured semiconductor, made from several thin layers of material with different band gaps. The layers can be anything from a few atoms in thickness right up to micrometre size and the materials used are typically gallium arsenide (GaAs) or aluminium gallium arsenide (AlGaAs). The band gap material may also be a material such as diamond or doped diamond. It also includes materials such as the alkali metal oxides or the alkaline earth oxides. FIG. 1B discloses another embodiment of the present invention, in which the band gap material is deposited as a layer on a metal collector 210.

For the embodiments shown in FIGS. 1A and 1B, the space d between the two electrodes is of the order of 1-20 nm, and is maintained at this distance by a housing (not shown). Preferably the space between the electrodes is evacuated, or filled with an inert gas at low pressure, such as argon.

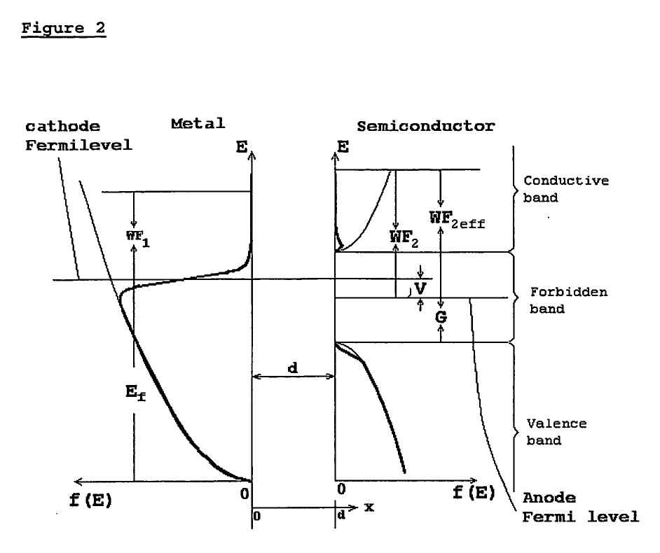

Without wishing to be bound by a particular doctrine, the operation of the tunnel diode of the present invention may be understood by referring to FIG. 2, which shows various energy levels for a metal cathode (or emitter) positioned a small distance d away from a semiconductor anode (or collector). Distance d is preferably of the order of 1-100 nm, most preferably 1-10 nm. The semiconductor shown in FIG. 2 is pure semiconductor. It is well known that the Fermi level of such a semiconductor lies near the center of forbidden band G.

The vertical axis in FIG. 2 represents potential energy, with zero signifying the bottom of the metal conductive band. The horizontal axis represents the electron and electron state density f(E) in the metal and in the semiconductor, and the distance x between electrodes. Electron density in the conducting band of the metal and in the conducting (upper) and valence (lower) bands of semiconductor is shown by the bold lines, and the thin lines represent the electron states density. The difference between Fermi levels of the electrodes, V, is the applied voltage (V bias).

WF₁ is the work function of the metal, WF₂ is the work function of the semiconductor, and G is the forbidden band. WF₂ is the “thermionic” work function, i.e. the energy interval between the Fermi level and the vacuum level; then WF_{2eff}=WF₂−G/2 is the energy interval between the bottom of the conductive band and the electron energy level in the vacuum.

If the forbidden band G of the semiconductor is not too large (for example, about 0.5-1 eV), thermal excitation of electrons from the valence band into the conductive band is sufficiently fast for electrical current transmission in the semiconductor (especially if it is a layer ˜10-15 nm “thin” for conductivity and “thick” for tunnel processes).

From FIG. 2 it can be seen that tunnel exchange by electrons between electrodes is possible only above or below the forbidden band, because the forbidden band does not have any permitted electron states. Since the probability for tunneling is much less for states below the forbidden band than for states above it, tunneling from below the forbidden band can be neglected, and it is only tunneling from the conductive band that needs to be taken into account. This region has an energy level of G/2−V above the Fermi level of emitter.

What this means is that the use of a semiconductor collector prevents tunneling from emitter to collector for electrons which lie opposite the forbidden gap of semiconductor, i.e. just below Fermi level of emitter. Moreover, the use of a semiconductor with a gap of E₀ between the Fermi level and the bottom of the conductive band, tunneling from emitter for electrons with energy less E₀ is prevented.

A further aspect of the invention is that the application of a voltage bias V between electrodes allows electrons with energies greater than E₀−V to tunnel. In other words, the tunnel diode of the present invention is equivalent to a thermionic diode with an “artificial” work function of E₀−V. The magnitude of the artificial work function can be adjusted for the operating conditions, especially for operating temperature, by the choice of E₀ and V.

Referring again to FIG. 2 it can be seen that the majority of electrons that tunnel will carry away from the emitter energy of not less than G/2−V. As discussed above, this potential threshold (G/2−V) is equivalent to the emitter work function in thermionic diodes, and can be adjusted to optimal low (for example, ˜0.4-0.3 eV for operation at temperatures ˜250-350 K) value by applied voltage V. In effect this means that the tunnel diode of the present invention is as efficient as a thermionic diode for cooling, and that this level of cooling can be achieved in practice without resorting to exotic materials having low work functions. In fact, its “work function” can be chosen, and the cooling power and efficiency manipulated, by varying V and gap size d.

For semiconductors with a large E₀ (for example, E₀>1 eV), the tunnel current from the emitter will be too small at low V values of ˜0.1-0.2V. However at V values of 0.7-0.75V, the effective barrier will be optimum for room temperature cooling (0.3-0.4 eV). In other words, adjusting the bias level so that E₀−V=0.3-0.35 eV corresponds to optimum emitter WF of thermionic cool diode for chosen emitter and collector temperatures. Even if E₀ is in the range 3-4 eV, V can be set at 2.7-3.7V. Of course, such high biases values will give lower efficiency, but reasonable currents can be obtained at d=˜5 nm, compared to d=˜2 nm for ˜10 A/cmˆ2 currents and a V˜0.1V for high efficiency cooling operation.

For a semiconductor, varying the electron donor concentration allows the position of the Fermi level to be moved from the centre of the forbidden gap to nearer the bottom of the conductive band. This means that a range of semiconductors may be used, including Ge (G=0.75 ev), Si (G=1.12 eV), GaAs (G=1.43) or SiC (G=2.4-3.4 eV), and the effective work function be modified to any appropriate value, up to 0.1-0.01 eV or less. Alternatively a hetero-structure semiconductor may be utilized. For operation at temperatures below room range the semiconductor may be appropriately doped, since it is well-known that semiconductors with high doping by an electron donor dopant can have E₀ up to 0. At the higher temperature ranges, semiconductors with less dopant concentration and thus a higher E₀ may be used (for example, for room temperature operation, E₀˜0.3-0.6 eV).

Thus there is a wide range of semiconductor materials that may be used as the band gap material in the tunnel gap diode of the present invention for cooling applications. The two key design features are that (i) the band gap material used must have sufficient conductivity for working currents (1-100 A/cm2); and (ii) the band gap material should give low WF (˜1-1.2 eV) after Cs+O₂ treatment (or by treatment of another electropositive atoms such as another alkali metals, alkali-earth metals (Ba, Sr), la, Y, Sc etc., and other electronegative atoms (F and another halogens, S, etc).

For power generating applications the output voltage is small (˜0.1V or less), and so E₀ should be less ˜0.2-0.4 eV for emitter temperatures 300-400 K. But for higher temperatures (500-600-700 K) the preferred value for E₀ rises, and for 700-800 K it can be ˜1 eV.

### EXAMPLE

In one embodiment, pure Ge is the semiconductor. It has G=0.75 eV, and G/2=0.375 eV, a little more than optimum WF for thermionic diode for Tc=300 K (˜0.33 eV). Even at room temperature, Ge has electron concentration in conductive band ˜10¹³ cm⁻³, which is sufficient for electrical conductivity for thin layer. If it is assumed that electrodes are treated by Cs and O₂ and has WF1=WF2=1 eV, then the output parameters for cooling with d=2.5 nm, Tc=300 K, Th=350 K are given below:

| | j, | Qc, | W, | | | hcool/hcool |
|---|---|---|---|---|---|---|
| V, V | A/cm2 | W/cm2 | W/cm2 | COP | hcool | Carnot |
| 0.10 | 1.76 | 0.63 | 0.177 | 3.56 | 0.78 | 0.91 |
| 0.14 | 6.82 | 2.22 | 0.796 | 2.32 | 0.699 | 0.816 |
| 0.20 | 36.6 | 9.70 | 7.315 | 1.32 | 0.57 | 0.665 |

Here j is resulting diode current, Qc cooling power, W = j*V = spent power.

Calculations were fulfilled with some simplifications as follows.

For elementary tunnel current from emitter, which is produced by electrons of the metal conductive band with energy interval E, E+dE and with energy Ex, Ex+dEx in direction normal to the emitted surface, we use expression

$${dj}_{+} = q \frac{4 π m}{{h}^{3}} \frac{1}{1 + exp \frac{E - {E}_{f}}{{kT}_{c}}} ( 1 - \frac{1}{1 + exp \frac{E + V - {E}_{f}}{{kT}_{a}}} ) P ( {E}_{x} ) {dE}_{x} dE \qquad ( 1 )$$

where q and m is the charge and mass of electron, h and k—Plank and Boltzmann constants, T_{c} and Tₐ—emitter and collector temperatures, E_{f}—Fermi energy of emitter, P(Eₓ)—tunnel probability for electrons with normal energy Eₓ. Tunnel probability was determined in BWK approximation:

$$P ( {E}_{x} ) = exp [ - \frac{4 π}{h} {\int }_{{x}_{2}}^{{x}_{2}} \sqrt{2 m ( V ( x ) q - {E}_{x} )} ⅆ x ] \qquad ( 2 )$$

where V(x) is potential distribution into the gap, x₁ and x₂ are the roots of equation
V(x)=Eₓ (3)

For potential distribution equation (4) was used to take into account mirror image forces:

$$V ( x ) = \frac{WF}{q} - V \frac{x}{d} - \frac{q}{4 π {ɛ}_{0}} [ \frac{1}{4 x} - \frac{1}{2} {\sum }_{n = 1}^{} ( \frac{nd}{{n}^{2} {d}^{2} - {x}^{2}} - \frac{1}{nd} ] \qquad ( 4 )$$

where ε₀ is vacuum permittivity, x—coordinate in direction normal to the surface. Assuming the replacement energy for electrons is E_{f}, this gives the following elementary heat flux generated by the by elementary tunnel current:

$${dQ}_{+} = q \frac{4 π m}{{h}^{3}} \frac{E - {E}_{f}}{1 + exp \frac{E - {E}_{f}}{{kT}_{c}}} ( 1 - \frac{1}{1 + exp \frac{E + V - {E}_{f}}{{kT}_{a}}} ) P ( {E}_{x} ) {dE}_{x} dE \qquad ( 5 )$$

The following analogous expressions were used for elementary tunnel current and heat flux from collector to emitter:

$$\begin{matrix}{dj}_{+} = q \frac{4 π m}{{h}^{3}} \frac{1}{1 + exp \frac{E + V - {E}_{f}}{{kT}_{a}}} ( 1 - \frac{1}{1 + exp \frac{E + {E}_{f}}{{kT}_{c}}} ) P ( {E}_{x} ) {dE}_{x} dE & ( 6 ) \\ {dQ}_{+} = q \frac{4 π m}{{h}^{3}} \frac{E - {E}_{f}}{1 + exp \frac{E + V - {E}_{f}}{{kT}_{a}}} ( 1 - \frac{1}{1 + exp \frac{E - {E}_{f}}{{kT}_{c}}} ) P ( {E}_{x} ) {dE}_{x} dE & ( 7 )\end{matrix}$$

Integrating of (1) and (5-7) with corresponds limits for E and Eₓ yields the relationship between current and heat flux between electrodes and to calculate parameters of a cooling device.

This shows that, for low biases, there is very high efficiency, but relatively low cool power. But with a small increase of V the cooling power increases by more than one order (to ˜10 W/cm²), whilst the efficiency falls by only a small amount (COP>1).

Note, by a small decrease of the gap (to 2 nm) the output parameters can be significantly improved:

| | j, | Qc, | W, | | | hcool/hcool |
|---|---|---|---|---|---|---|
| V, V | A/cm2 | W/cm2 | W/cm2 | COP | hcool | Carnot |
| 0.1 | 44.6 | 15.6 | 4.46 | 3.57 | 0.78 | 0.908 |

Importantly, these data show that it is possible to have a good cooling performance even for WF>1 eV at thinner gaps. For example, for WF=1.3 eV (a common value for anodes of standard thermionic converters), and a gap d=1.6 nm we have:

| | j, | Qc, | W, | | | hcool/hcool |
|---|---|---|---|---|---|---|
| V, V | A/cm2 | W/cm2 | W/cm2 | COP | hcool | Carnot |
| 0.12 | 19.3 | 6.13 | 2.32 | 2.646 | 0.726 | 0.847 |

Of course, it is possible to use other semiconductor materials, which can give still better performance, including specially formulated materials specific for these applications. Of course, for different cooling tasks it different materials will be required. Also, use of semiconductor collector is favorable for power producing too. For this purpose special materials are optimal.

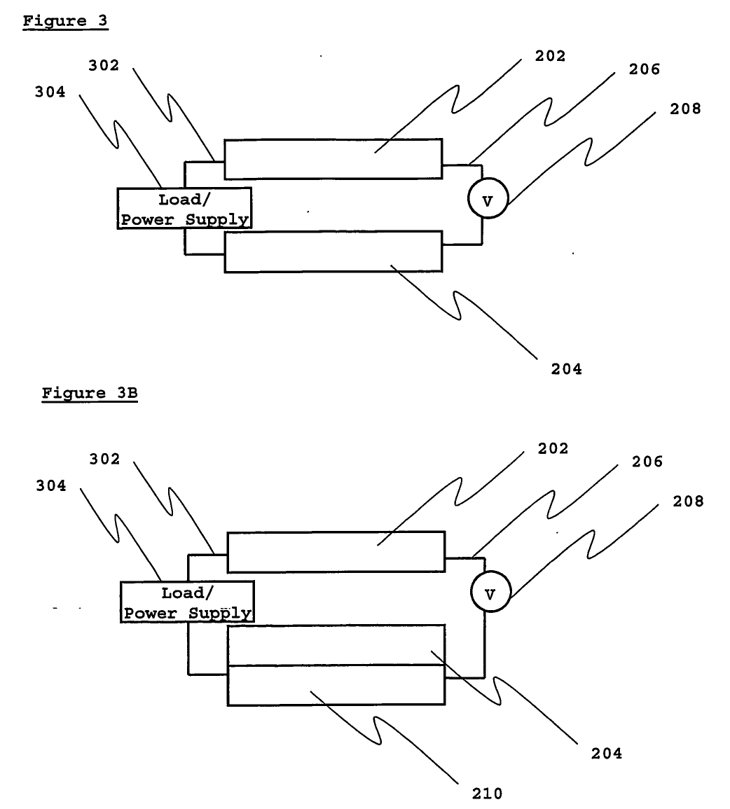

Referring now to FIG. 3, which shows in diagrammatic form a heat pump/power converter of the present invention comprising an emitter, a collector and a bias circuit. In FIG. 3A, the collector is a semiconductor material. In FIG. 3B, the collector is a layer of a semi conductor material on a metal electrode.

For a vacuum diode heat pump, the tunnel gap diode is connected via an external circuit 302 to a power supply. Emitter 202 is in thermal contact with an object to be cooled (not shown), and collector 204 is in thermal contact with a heat sink (not shown).

For a heat to electricity converter, the tunnel gap diode is connected via an external circuit 302 to an electrical load. Emitter 202 is in thermal contact with a heat source (not shown), and collector 204 is in thermal contact with a heat sink (not shown).

### INDUSTRIAL APPLICABILITY

Devices made according to the present invention may be used in diode devices, vacuum diode devices, heat pumps, and the like. For example, heat pipes based on this invention have specific power and efficiency commensurate with, or better than, common compressor refrigerators employing evaporated heat carrier, and specific weight and volume commensurate with (or better than) thermoelectrical (semiconductor) ones. Because production of such heat pipes can be based on nanotechnology and micromachining, they should be sufficiently cheap to manufacture. As a result, they can be used with great economical effect in practically all areas of refrigerating: domestic and industry refrigerator (especially freight and ship refrigerators), air-conditioning, cooling of technical and especially electron devices, including computer devices (processors first of all), sensors (especially infrared ones), refrigerators for aerospace applications, etc. In prospect, they should replace most, if not all, parts of existing refrigerators. Combination of high efficiency and small specific weight and volume, together with the ability to work significantly below room temperatures, promises numerous new, and unpredictable applications.

While this invention has been described with reference to numerous embodiments, it is to be understood that this description is not intended to be construed in a limiting sense. Various modifications and combinations of the illustrative embodiments will be apparent to persons skilled in the art upon reference to this description. It is to be further understood, therefore, that numerous changes in the details of the embodiments of the present invention and additional embodiments of the present invention will be apparent to, and may be made by, persons of ordinary skill in the art having reference to this description. It is contemplated that all such changes and additional embodiments are within the spirit and true scope of the invention as claimed below.

All publications and patent applications mentioned in this specification are indicative of the level of skill of those skilled in the art to which this invention pertains. All publications and patent applications are herein incorporated by reference to the same extent as if each individual publication or patent application was specifically and individually indicated to be incorporated by reference.

1. A tunnel diode in which the collector comprises a band gap material, said band gap material being a crystal material having filled zero temperature valence band and empty conductive band.

2. The tunnel diode of claim 1 additionally comprising an emitter coated with a layer of a band gap material.

3. The tunnel diode of claim 1 in which the collector comprises a layer of band gap material deposited on a metal collector.

4. The tunnel diode of claim 3 in which said layer of material has a thickness greater than the mean distance of relaxation of electrons tunneling from said emitter.

5. The tunnel diode of claim 1 in which the band gap material is selected from the group consisting of: a semiconductor, a hetero-structured semiconductor, a dielectric, a diamond material, an alkali metal oxide and an alkaline earth oxide.

6. The tunnel diode of claim 1 in which the band gap material is selected from the group consisting of: Ge, Si, GaAs, SiC and AlGaAs.

7. The tunnel diode of claim 1 in which the electrodes are separated by a gap in the range 1-100 nm.

8. The tunnel diode of claim 1 tin which the electrodes are separated by a gap in the range 1-10 nm.

9. The tunnel diode of claim 1 in which a gap between the emitter and collector electrodes is evacuated.

10. A vacuum diode heat pump comprising the tunnel diode of claim 1.

11. A heat to electricity converter comprising the tunnel diode of claim 1.

12. A method for promoting the tunneling of electrons having an energy level higher than the Fermi level from an emitter surface, comprising the step of positioning a collector comprising a band gap material at a distance within the tunneling range of said electrons, said band gap material being a crystal material having filled zero temperature valence band and empty conductive band.

13. A method for preventing back tunneling of electrons in a tunnel diode comprising the step of coating a collector with a layer of a band gap material, said band gap material being a crystal material having filled zero temperature valence band and empty conductive band.

14. The method of claim 12 in which the collector comprises a layer of band gap material deposited on a metal collector.

15. The method of claim 14 in which said layer of material has a thickness greater than the mean distance of relaxation of electrons tunneling from said emitter.

16. The method of claim 12 in which the band gap material is selected from the group consisting of: a semiconductor, a hetero-structured semiconductor, a dielectric, a diamond material, an alkali metal oxide and an alkaline earth oxide.

17. The method of claim 12 in which the band gap material is selected from the group consisting of: Ge, Si, GaAs, SiC and AlGaAs.

18. The method of claim 12 in which the electrodes are separated by a gap in the range 1-100 nm.

19. The method of claim 12 in which the electrodes are separated by a gap in the range 1-10 nm.

20. The method of claim 12 in which a gap between the emitter and collector electrodes is evacuated.
